(19) United States
(12) Patent Application Publication
(10) Pub. No.: US 2007/0298611 A1
(43) Pub. Date: Dec. 27, 2007

(54) Selective barrier slurry for chemical mechanical polishing

(76) Inventor: Jinru Bian, Newark, DE (US)

Correspondence Address: ROHM AND HAAS ELECTRONIC MATERIALS;CMP HOLDINGS, INC., 451 BELLEVUE ROAD, NEWARK, DE, 19713, US

(21) Appl. No.: 11/475,346

(22) Filed: Jun. 27, 2006

(51) Int. Cl. H01L 21/461; C09K 13/00

(52) U.S. Cl. 438/685; 252/79.1; 438/693

(57) ABSTRACT

The present invention provides an aqueous polishing composition useful for polishing semiconductor substrates. The composition comprises 0.05 to 50 weight percent abrasive and 0.001 to 5 weight percent iota type carrageenan. The iota type carrageenan has a concentration useful for accelerating the removal rate of tantalum, tantalum nitride and other tantalum-containing materials.

### BACKGROUND OF THE INVENTION

This invention relates to polishing of semiconductor wafers and, more particularly, to compositions and methods for removing wafer layers, such as, barrier materials in the presence of another layer, such as a low-k dielectric layer.

Typically, semiconductor substrates have a silicon base and dielectric layers containing multiple trenches arranged to form a pattern of circuit interconnects within the dielectric layer. These trench patterns have either a damascene structure or dual damascene structure. In addition, typically one to as many as three or more capping layers coat the trench patterned dielectric layer with a barrier layer covering the capping layer or capping layers. Finally, a metal layer covers the barrier layer and fills the patterned trenches. The metal layer forms circuit interconnects that connect dielectric regions and form an integrated circuit.

The capping layers can serve different purposes. For example, a capping layer, such as, silicon carbide nitride coating dielectrics, may act as a polishing stop to protect underlying dielectrics from removal during polishing. The silicon carbide nitride's nitrogen concentration varies with manufacturer; and it may contain up to approximately 50 atomic percent nitrogen—if the nitride content is zero, then the stopping layer has a chemistry of silicon carbide. In addition, a silicon dioxide layer, silicon nitride layer or a combination of the two layers, may correct topography above the stopping layer. Typically, a barrier layer, such as a tantalum or tantalum nitride barrier layer, coats the capping layer and a metal conductive layer covers the barrier layer to form the interconnect metal.

Chemical mechanical planarization or CMP processes often include multiple polishing steps. For example, an initial planarization step removes a metal layer from underlying barrier dielectric layers to planarize the wafer. This first-step polishing removes the metal layer, while leaving a smooth planar surface on the wafer with metal-filled trenches that provide circuit interconnects planar to the polished surface. First-step polishing steps tend to remove excess interconnect metals, such as copper, at a relatively high rate. After the first-step polishing, a second-step polishing process typically removes a barrier that remains on the semiconductor wafer. This second-step polishing removes the barrier from its underlying dielectric layer to provide a planar polished surface on the dielectric layer. The second-step polishing may stop on a capping layer, remove all capping layers or remove some of the underlying dielectric layer.

Unfortunately, CMP processes often result in the excess removal of unwanted metal from circuit interconnects or “dishing”. This dishing can result from, both first-step polishing and second-step polishing. Dishing in excess of acceptable levels causes dimensional losses in the circuit interconnects. These thin areas in the circuit interconnects attenuate electrical signals and can impair continued fabrication of dual damascene structures. In addition to dishing, the CMP processes often remove excessive amounts of the dielectric layer in an effect known as “erosion”. Erosion that occurs adjacent to the interconnect metal can introduce dimensional defects in the circuit interconnects. Furthermore, erosion is a particular problem for low-k and ultra-low-k dielectrics. In a manner similar to dishing, these defects contribute to attenuation of electrical signals and impair subsequent fabrication of dual damascene structures.

After removing the barrier layer and any undesired capping layers, a first capping layer stop, such as a silicon carbide nitride stopping layer, often prevents the CMP process from damaging the dielectric. This stopping layer typically protects the underlying dielectrics to avoid or alleviate dielectric erosion by controlling removal rate. The removal rates of the barrier and other capping layers (such as, silicon nitride and silicon dioxide), versus, a removal rate of the stopping layer are examples of selectivity ratios. For purposes of this application, selectivity ratio refers to the ratio in removal rate as measured in angstroms per minute.

Singh et al., in WO Pat. Pub. No. 03/072670, disclose the optional use of nonionic, anionic, cationic and zwitterionic surfactants to improve selectivity. This patent publication, however, does not disclose a specific formulation useful for limiting low-k dielectric erosion.

There is an unsatisfied demand for a composition that selectively removes barrier materials and capping materials (such as, silicon nitride and silicon dioxide) without removing excessive amounts of dielectric layers, such as low-k dielectric layers. In addition, there is a need for a slurry that polishes semiconductor wafers as follows: removes barrier materials; reduces interconnect dishing, reduces dielectric erosion; avoids peeling of the dielectric; and operates with or without a silicon carbide-nitride stopping layer.

### STATEMENT OF THE INVENTION

An aspect of the invention includes an aqueous polishing composition useful for polishing semiconductor substrates comprising: 0.05 to 50 weight percent abrasive; and 0.001 to 5 weight percent iota type carrageenan, the iota type carrageenan having a concentration useful for accelerating the removal rate of tantalum, tantalum nitride and other tantalum-containing materials.

Another aspect of the invention includes an aqueous polishing composition useful for polishing semiconductor substrates comprising: 0.1 to 50 weight percent abrasive; and 0.01 to 2 weight percent iota type carrageenan, the iota type carrageenan having a concentration useful for accelerating barrier removal rate and useful for decreasing the removal rate of at least one coating selected from the group of SiC, SiCN, Si₃N₄ and CDO.

Another aspect of the invention includes an aqueous polishing composition useful for polishing semiconductor substrates comprising: 0.1 to 50 weight percent silica abrasive; and 0.05 to 1 weight percent iota type carrageenan, the iota type carrageenan having a concentration useful for accelerating barrier removal rate and useful for decreasing the removal rate of at least one coating selected from the group of SiC, SiCN, Si₃N₄ and CDO.

Another aspect of the invention includes a method of polishing a semiconductor substrate including the step of polishing with an aqueous polishing composition, the composition including 0.05 to 50 weight percent abrasive; and 0.001 to 5 weight percent iota type carrageenan, the iota type carrageenan for removing tantalum, tantalum nitride and other tantalum-containing materials and maintaining a hardmask layer selected from at least one of SiC, SiCN and Si₃N₄.

### DETAILED DESCRIPTION OF THE INVENTION

The slurry and method provide unexpected selectivity for removing barrier materials, such as tantalum, tantalum nitride and other tantalum-containing materials, while not removing excess low k materials, such as carbon-doped oxide (CDO). The slurry relies upon an iota carrageenan to selectively remove tantalum, tantalum nitride and, tantalum-containing barrier layers while stopping or removing a silicon nitride or silicon carbide nitride layer. This selectivity reduces dishing of interconnect metal and erosion of dielectric layers. Furthermore, the slurry can remove barrier materials and capping layers such as, silicon nitride, organic caps and dielectrics without peeling or delaminating fragile low-k dielectric layers from semiconductor wafers. Another benefit of these slurries is the composition's ability to stop at silicon carbon doped oxide (CDO) layers.

It has been found that addition of a iota carrageenan in a slurry with an abrasive can enhance the removal rate of barrier materials. Carrageena represent naturally occurring complex mixtures of sulfated polysaccharides extracted from red seaweed. In particular, carrageenans are high molecular weight polysaccharides made up of repeating galactose units and 3,6 anhydrogalactose (3,6-AG), both sulfated and non-sulfated. There are three commercial types of carrageenan: Kappa, Iota and Lambda (κ, ι, and λ). The units are joined by alternating alph1-3 and beta 1-4 glycosidic linkages. The primary difference, which influences the properties of kappa, iota and lambda, is the number and position of the ester sulfate groups on the repeating units. Each unit of lambda carrageenan contains an average of about 1.5 sulfate groups; each unit of iota-carrageenan contains an average of about 1 sulfate group, and each unit of kappa-carrageenan contains an average of about 0.5 sulfate groups. Basically, the lambda with more sulfated groups has less gelling potential. The lambda-carrageenan typically has greater than one sulfate group for each unit. The kappa-carrageenan, with more anhydrate linkages, has more gelling potential, due to its greater “kink” structure. The lambda-carrageenan serves to increase viscosity in commercial applications. Kappa forms brittle and firm gel, which is “non-curable” while iota forms “elastic” gel which is “reversible” after the gel has broken. Furthermore the one containing more sulfate groups is more water soluble or has a high water solubility. The addition of the iota carrageenan can enhance the removal rate of the barrier layer.

The iota carrageenans are present in an amount of 0.001 weight percent to 5 weight percent. For purposes of this specification, all concentrations have values expressed in weight percent based upon the total weight of the polishing composition, unless specifically noted otherwise. Preferably, the iota-carrageenan is present in an amount of 0.01 to 2 weight percent and most preferably, 0.05 to 1 weight percent.

The polishing composition contains 0.05 to 50 weight percent abrasive to facilitate barrier removal or combined barrier and mask/cap removal—depending upon the integration scheme, the polishing composition may serve to remove the barrier layer or to first remove a barrier layer and then remove a cap layer. The abrasive is preferably a colloidal abrasive. Example abrasives include inorganic oxides, metal borides, metal carbides, metal nitrides, polymer particles and mixtures comprising at least one of the foregoing. Suitable inorganic oxides include, for example, silica (SiO₂), alumina (Al₂O₃), zirconia (ZrO₂), ceria (CeO₂), manganese oxide (MnO₂), or combinations comprising at least one of the foregoing oxides. Modified forms of these inorganic oxides such as polymer-coated inorganic oxide particles and inorganic coated particles may also be utilized if desired. Suitable metal carbides, boride and nitrides include, for example, silicon carbide, silicon nitride, silicon carbonitride (SiCN), boron carbide, tungsten carbide, zirconium carbide, aluminum boride, tantalum carbide, titanium carbide, or combinations comprising at least one of the foregoing metal carbides, boride and nitrides. Diamond may also be utilized as an abrasive if desired. Alternative abrasives also include polymeric particles and coated polymeric particles. The preferred abrasive is silica.

It is desired to use the abrasive in an amount of 0.1 to 50 weight percent. Within this range, it is desirable to have the abrasive present in an amount of greater than or equal to 0.2 weight percent, and preferably greater than or equal to 0.5 weight percent. Also desirable within this range is an amount of less than or equal to 15 weight percent, and preferably less than or equal to 10 weight percent.

The abrasive has an average particle size of less than or equal to 150 nanometers (nm) for preventing excessive metal dishing and dielectric erosion. For purposes of this specification, particle size refers to the average particle size of the abrasive. It is desirable to use a colloidal abrasive having an average particle size of less than or equal to 100 nm, preferably less than or equal to 50 nm, and more preferably less than or equal to 40 nm. The least dielectric erosion and metal dishing advantageously occurs with colloidal silica having an average particle size of less than or equal to 40 nm. Decreasing the size of the colloidal abrasive to less than or equal to 40 nm, tends to improve the selectivity of the polishing composition; but it also tends to decrease the barrier removal rate. In addition, the preferred colloidal abrasive may include additives, such as dispersants, surfactants and buffers to improve the stability of the colloidal abrasive at acidic pH ranges. One such colloidal abrasive is colloidal silica from AZ Electronic Materials.

If the polishing composition does not contain abrasives, then pad selection and conditioning become more important to the chemical mechanical planarizing (CMP) process. For example, for some abrasive-free compositions, a fixed abrasive pad improves polishing performance.

The polishing composition may optionally contain a barrier removing agent, such as guanidine, formamidine or their derivatives to enhance the removal of barrier, such as tantalum, tantalum nitride, titanium and titanium nitride. The chemical mechanical planarizing composition can also optionally include complexing agents, chelating agents, pH buffers, biocides and defoaming agents.

Optionally, the removal rate of barrier layers, such as tantalum, tantalum nitride, titanium and titanium nitride is advantageously optimized by the use of the oxidizing agent. Suitable oxidizers include, for example, hydrogen peroxide, monopersulfates, iodates, magnesium perphthalate, peracetic acid and other peracids, persulfates, bromates, periodates, nitrates, iron salts, cerium salts, manganese (Mn) (III), Mn (IV) and Mn (VI) salts, silver salts, copper salts, chromium salts, cobalt salts, halogens, hypochlorites, or combinations comprising at least one of the foregoing oxidizers. The preferred oxidizer is hydrogen peroxide. It is to be noted that the oxidizer is typically added to the polishing composition just prior to use and in such instances the oxidizer is contained in a separate package.

It is desirable to use an amount of 0 to 10 wt % oxidizer. Within this range, it is desirable to have oxidizer at an amount of greater than or equal to 0.1 wt %. Also desirable within this range is an amount of less than or equal to 5 wt % oxidizer. Most preferably, the composition contains 0.1 to 5 wt % oxidizer. Adjusting the amount of oxidizer, such as peroxide can also control the metal interconnect removal rate. For example, increasing the peroxide concentration increases the copper removal rate. Excessive increases in oxidizer, however, provide an adverse impact upon polishing rate.

The polishing composition may have either an acidic pH or alkaline pH. Suitable metals used for the interconnect include, for example, copper, copper alloys, gold, gold alloys, nickel, nickel alloys, platinum group metals, platinum group metal alloys, silver, silver alloys, tungsten, tungsten alloys and mixtures comprising at least one of the foregoing metals. The preferred interconnect metal is copper. In acidic polishing compositions or alkaline polishing compositions and slurries that utilize oxidizers such as hydrogen peroxide, both the copper removal rate and the static etch rate are high primarily because of oxidation of the copper. In order to reduce the removal rate of the interconnect metal the polishing composition employs a corrosion inhibitor. The corrosion inhibitors function to reduce removal of the interconnect metal. This facilitates improved polishing performance by reducing the dishing of the interconnect metal.

The inhibitor is typically present in an amount up to 6 wt %—the inhibitor may represent a single or a mixture of inhibitors to the interconnect metal. Within this range, it is desirable to have an amount of inhibitor greater than or equal to 0.0025 wt %, preferably greater than or equal to 0.15 wt %. Also desirable within this range is an amount of less than or equal to 1 wt %, preferably less than or equal to 0.5 wt %. The preferred corrosion inhibitor is benzotriazole (BTA). The optimal amount of inhibitor in an acidic composition may be higher than that in an alkaline pH polishing composition.

Additional corrosion inhibitors include surfactants such as, for example, anionic surfactants, zwitterionic, nonionic surfactants, amphoteric surfactants and polymeric surfactants, or organic compounds, such as azoles. Suitable anionic surfactants include, for example, surfactants having a functional group, such as a sulfonate, a sulfate, a carboxylate, a phosphate, or a derivative of these functional groups, or combinations comprising at least one of the foregoing surfactants. A preferred anionic surfactant is sodium dodecylbenzenesulfonate. Suitable nonionic surfactants include, for example, silicon-based compounds, fluorine-based compounds, an ester, an ethylene oxide, an alcohol, an ethoxylate, an ether, a glycoside, or a derivative of these compounds, or a combination comprising at least one of the foregoing nonionic surfactants. Suitable amphoteric surfactants or polymers include, for example, polycarboxylates and their derivatives, polyacrylamides and their derivatives, cellulose, polyvinylalcohols and their derivatives, and polyvinylpyrrolidones and their derivatives. Suitable azoles that may be used as an inhibitor or in an inhibitor mixture include, for example, tolytriazole (TTA), imidazole and mixtures thereof. The most preferred secondary corrosion inhibitor is tolytriazole.

The polishing composition also includes inorganic or organic pH adjusting agents to reduce the pH of the polishing composition to an acidic pH or to increase the pH to an alkaline pH. Suitable inorganic pH reducing agents include, for example, nitric acid, sulfuric acid, hydrochloric acid, phosphoric acid, or combinations comprising at least one of the foregoing inorganic pH reducing agents. Suitable pH increasing agents include one of metal hydroxides, ammonium hydroxide, or nitrogen-containing organic base or combination of foregoing pH increasing agents.

The polishing composition operates at either an acidic pH or an alkaline pH. It is preferable to have the pH of the polishing composition between 1 and 14. Within this range it is desirable to have a pH of greater than or equal to 2 and lower than or equal to 12. The most preferred pH for the polishing composition is 3 to 10.

Optionally, the polishing composition may contain a chelating or complexing agent to adjust the copper removal rate relative to the barrier metal removal rate. The chelating agent improves the copper removal rate by forming a chelated metal complex with copper. Suitable chelating agents include, for example, carboxylic acid, an amino-carboxylic acid and derivatives thereof, or combinations comprising at least one of the foregoing chelating agents. Preferably, the chelating agent is present in the polishing composition in an amount of less than or equal to 2 wt %. Optionally, the polishing composition can also include buffering agents such as various organic and inorganic acids, and amino acids or their salts with a pKa in the pH range of 1.5 to less than 13. Optionally, the polishing composition can further include defoaming agents, such as an non-ionic surfactants including esters, ethylene oxides, alcohols, ethoxylate, silicon compounds, fluorine compounds, ethers, glycosides and their derivatives. The defoaming agent may also be an amphoteric surfactant.

The polishing composition enables the CMP apparatus to operate with a low pressure of 2.5 to 15 kilopascals (kPa). Within this range, a pressure of 3 to 12 kPa, is preferred. The low CMP pad pressure improves polishing performance by reducing scratching and other undesired polishing defects and reduces damage to fragile materials. For example, low dielectric constant materials fracture and delaminate when exposed to high stresses. Further, the high barrier metal removal rate obtained by the polishing composition enables effective barrier metal removal rates and silicon oxide-containing layer, such as TEOS, removal rates using a low abrasive concentration and a small abrasive particle size. In an exemplary embodiment, the polishing composition can be adjusted or tuned so as to advantageously achieve a high barrier removal rate without any destruction to the capping layer. It can also advantageously be tuned to remove the capping layer without any damage to the low k or ultra-low k dielectric layer.

The composition accelerates barrier removal and decreases removal of at least one coating selected from the group consisting of SiC, SiCN and Si₃N₄ for at least one polishing pressure of less than 21.7 kPa (3 psi) as measured with a porous-filled polyurethane polishing pad pressure measured normal to a wafer. Preferably the at least one coating selected from the group consisting of SiC, SiCN and Si₃N₄ is a cap layer. For purposes of the specification, comparative removal refers to removal rates as measured with a porous-filled polyurethane polishing pad pressure measured normal to a wafer. A particular polishing pad useful for determining selectivity is the IC1010™ porous-filled polyurethane polishing pad. Since the composition will operate at a variety of polishing pressures, these data are for illustrating the efficacy of the composition, not for describing a specific operating pressure for the use of the composition. The polishing composition optionally has a barrier to cap selectivity of at least 2 to 1 as measured with a porous-filled polyurethane polishing pad pressure measured normal to a wafer with at least one polishing pressure less than 21.7 kPa. The integration scheme selected controls barrier selectivity.

Also, the process may stop on the dielectric layer. Typical dielectric materials include silicon oxide-containing materials derived from silanes such as tetratethylorthosilicate (TEOS), low k and/or ultra-low k organic materials, and CORAL® CVD SiOC commercially available from Novellus.

### EXAMPLES

### Example 1

The aqueous slurries tested contained Marine Colloids™ carrageenan supplied from FMC, Philadelphia, Pa. The specific kappa type carrageenan was Gelcarin GP 911 (Sample B) and the iota type carrageenan was Gelcarin GP-379 (Sample 1) and Seaspen PF (Sample 2), both from FMC. This experiment was conducted to determine the polishing performance of the polishing composition with varied carrageenan types and concentrations. This Example and all other Examples used a Strausbaugh polishing machine with an IC1010 polishing pad (Rohm and Haas Electronic Materials CMP Technologies) under downforce conditions of about 2 psi (13.8 kPa) and a polishing slurry flow rate of 200 cc/min, a platen speed of 120 RPM and a carrier speed of 114 RPM polishing the sample wafers (200 mm). All polishing slurries had a pH adjusted with KOH or HNO₃ and all slurries were made with a balance of deionized water. In the Examples, letters identify the comparative compositions and numbers represent embodiments of the invention.

TABLE 1

| | Silica | Additive | GHN | TaN | Ta | TEOS | CDO | SiCN | Cu | Si₃N₄ |
|---|---|---|---|---|---|---|---|---|---|---|
| Sample | (wt %) | (wt %) | (wt %) | (Å/min) | (Å/min) | (Å/min) | (Å/min) | (Å/min) | (Å/min) | (Å/min) |
| A | 4 | 0.0 | 1 | 1264 | 490 | 213 | 219 | 397 | 277 | 436 |
| B | 4 | 0.10 | 1 | 1304 | 517 | 245 | 183 | 116 | 451 | 143 |
| 1 | 4 | 0.30 | 1 | 1852 | 850 | 337 | 159 | 75 | 488 | 186 |
| 2 | 4 | 0.30 | 1 | 1485 | 610 | 254 | 150 | 125 | 538 | 164 |

GHN = guanidine hydronitrate.
All samples contained PL150H25 30 nm average particle size silica from AZ Electronic Materials, 0.15 wt % Benzotriazole and 0.5 wt % H₂O₂, pH = 4 and CDO was Coral ™ dielectric from Novellus Systems, Inc.

This Example shows that iota-carrageenan increases Ta/TaN removal rate and decreases SiCN and Si₃N₄ removal rate with no adverse impact on CDO rate. The kappa and iota type carrageenans did not have a significant effect on TEOS removal rate.

From the above experiments it may be seen that the use of the iota-carrageenan in the polishing compositions permits the differential removal rates for the barrier layers when compared with the removal rates for the capping layers. This advantageously permits the rapid removal of one layer over another, such as Ta/TaN in comparison to SiCN. For example, for a semiconductor having a barrier layer and a cap layer, it optionally permits the selectivity of barrier to cap to be greater than or equal to 2 to 1 or even greater than or equal to 5 to 1. The selectivity ratios are applicable to tantalum-containing layers deposited on SiC, SiCO, Si₃N₄ or SiCN cap layers. They are also applicable to single masks as shown in the Table 2 below. The polishing composition can also advantageously be tuned to remove the barrier layer without any damage to the low k or ultra-low k dielectric layer. The ability of these polishing compositions to remove various layers of the semiconductor substrate without any damage to the low k and/or ultra-low k dielectric layer is shown in the Table 2 below.

TABLE 2

| | | | | Removal Rate |
|---|---|---|---|---|
| Integration | | Interconnect | Integration | (RR) |
| Scheme # | Layer | structures | schemes for CMP | requirements |
| 1 | Dual coatings | TaN/TEOS/SiCN/ | Polish TaN and | High RR for |
| | | Low k or ultra-low k | TEOS layers; stop | TaN and TEOS |
| | | dielectric layer | polishing on | layers; Low RR |
| | | | SiCN and low k | for SiCN and |
| | | | or ultra-low k | low k or ultra- |
| | | | dielectric layer | low k dielectric |
| | | | | layer |
| 2 | Single | TaN/Si₃N₄ (or | Polish TaN layer; | High RR for |
| | coating | SiCN)/Low k or | stop polishing on | TaN; Low RR |
| | | ultra-low k | Si₃N₄ (or SiCN) | for Si₃N₄ (or |
| | | dielectric layer | and low k or | SiCN) and low |
| | | | ultra-low k | k or ultra-low k |
| | | | dielectric layer | dielectric layer |
| 3 | No coating | TaN/Low k or | Polish TaN layer; | High RR for |
| | | ultra-low k | stop polishing on | TaN; Low RR |
| | | dielectric layer | low k or ultra-low | for low k or |
| | | | k dielectric layer | ultra-low k |
| | | | | dielectric layer |

Table 2 shows various integration schemes that may be employed for selectively removing certain desired layers from a semiconductor substrate. For example, integration scheme 1 shows how the polishing composition may be advantageously utilized to selectively remove the TaN and TEOS layers from an interconnect structure comprising TaN, TEOS, SiCN and an ultra-low k dielectric layer respectively. The polishing composition removes the TaN and TEOS layer at a higher rate than the SiCN and CDO layer, thereby preserving the SiCN and the ultra-low k dielectric layer.

The polishing composition is utilized to adjust the removal rate of barrier layers from interconnect structures in integrated circuit devices. It can be adjusted or tuned so as to achieve a high barrier layer removal with reduced dishing to the interconnect metal or with stopping on a cap layer, such as a SiCN, or Si₃N₄ cap layer. In addition, if the capping layer is a top TEOS layer deposited on a bottom layer and the bottom layer is a SiC, SiCN, Si₃N₄ or SiCO, then the composition can remove the top layer and leave at least a portion of the bottom layer. This selective TEOS removal is particularly effective for protecting low k and ultra-low k dielectrics with a cap layer.

1. An aqueous polishing composition useful for polishing semiconductor substrates comprising:
0.05 to 50 weight percent abrasive; and
0.001 to 5 weight percent iota type carrageenan, the iota type carrageenan having a concentration useful for accelerating the removal rate of tantalum, tantalum nitride and other tantalum-containing materials.

2. The composition of claim 1, wherein the iota type carrageenan is useful for decreasing the removal rate of at least one coating selected from the group of SiC, SiCN, Si₃N₄ and CDO.

3. The composition of claim 1, wherein the abrasive is selected from at least one of inorganic oxides, metal borides, metal carbides, metal nitrides and polymer particles.

4. An aqueous polishing composition useful for polishing semiconductor substrates comprising:
0.1 to 50 weight percent abrasive; and
0.01 to 2 weight percent iota type carrageenan, the iota type carrageenan having a concentration useful for accelerating barrier removal rate and useful for decreasing the removal rate of at least one coating selected from the group of SiC, SiCN, Si₃N₄ and CDO.

5. The composition of claim 4, wherein the iota type carrageenan is useful for decreasing the removal rate of SiCN.

6. The composition of claim 4, wherein the abrasive is selected from at least one of alumina, ceria and silica.

7. An aqueous polishing composition useful for polishing semiconductor substrates comprising:
0.1 to 50 weight percent silica abrasive; and
0.05 to 1 weight percent iota type carrageenan, the iota type carrageenan having a concentration useful for accelerating barrier removal rate and useful for decreasing the removal rate of at least one coating selected from the group of SiC, SiCN, Si₃N₄ and CDO.

8. The composition of claim 7, wherein the lambda type carrageenan is useful for decreasing the removal rate of SiCN.

9. The composition of claim 7, wherein the composition includes a benzotriazole corrosion inhibitor.

10. A method of polishing a semiconductor substrate including the step of polishing with an aqueous polishing composition, the composition including 0.05 to 50 weight percent abrasive; and 0.001 to 5 weight percent iota type carrageenan, the iota type carrageenan for removing tantalum, tantalum nitride and other tantalum-containing materials and maintaining a hardmask layer selected from at least one of SiC, SiCN and Si₃N₄.
